(19) United States
(12) Patent Application Publication
(10) Pub. No.: US 2024/0234418 A9
(43) Pub. Date: Jul. 11, 2024

(54) OPTIMIZATION OF VERTICAL TRANSPORT FIELD EFFECT TRANSISTOR INTEGRATION

(71) Applicant: QUALCOMM Incorporated, San Diego, CA (US)

(72) Inventors: Xia Li, San Diego, CA (US); Bin Yang, San Diego, CA (US); Haining Yang, San Diego, CA (US)

(21) Appl. No.: 18/047,954

(22) Filed: Oct. 19, 2022

(51) Int. Cl. H01L 27/092; H01L 21/822; H01L 21/8238; H01L 29/417; H01L 29/66; H01L 29/78

(52) U.S. Cl. CPC H01L 27/0922; H01L 21/8221; H01L 21/823871; H01L 21/823885; H01L 29/41741; H01L 29/66666; H01L 29/7827

(57) ABSTRACT

A vertical transport field effect transistor (VTFET) comprising: a plurality of FET structures on a substrate; the plurality of FET structures comprising: a first n-type FET structure oriented in a first plane direction relative to the substrate; and a first p-type FET structure oriented in a second plane direction relative to the substrate; wherein the first n-type FET structure and the first p-type FET structure each comprises a FIN having a FIN height, H, wherein H defines the FIN height orthogonal to a surface of the substrate, each FIN being configured to transport charge carriers orthogonal to the surface of the substrate along the FIN height.

### BACKGROUND

### Field of the Disclosure

The present invention is directed to vertical transport field effect transistors (VTFET). In particular, it is directed to improvements in the performance and integration of VTFETs.

### Description of Related Art

For many years, semiconductor design and fabrication has been centered around the use and integration of lateral field effect transistors (FETs). In brief, lateral FETs are described as such due to charge carriers being transported “laterally” through the device parallel to the device substrate surface. The maximum feature size in a lateral FET is limited by the connected gate pitch (CGP), which is a measurement of a minimum distance between one transistor gate and another. For example, Jagannathan et. al. (Vertical-Transport Nanosheet Technology for CMOS Scaling beyond Lateral-Transport Devices, IEDM 2021) note that gate length of a lateral FET is limited to ˜0.3×CGP, spacer width is limited to ˜0.1×CGP while the contact length is limited to ˜0.3×CGP. Advances in manufacturing techniques mean that lateral FETs are reaching these fundamental scaling limits. However, moving to a vertical transport field effect transistor VTFET (i.e. where charge carries move “vertically” perpendicular to a substrate surface) has the effect of removing the gate, spacer and contact out of the CGP and thus provides for continued scaling of device features.

While VTFET provides for advancement in device scaling compared to lateral FET, there remains scope for improvement in the performance and integration of VTFET.

### SUMMARY

A vertical transport field effect transistor (VTFET) comprising: a plurality of FET structures on a substrate; the plurality of FET structures comprising a first n-type FET structure oriented in a first plane direction relative to the substrate; a first p-type FET structure oriented in a second plane direction relative to the substrate; and the first n-type FET structure and the first p-type FET structure each comprises a channel comprising a FIN, having a FIN height, H, wherein H defines the FIN height orthogonal to a surface of the substrate, each FIN being configured to transport charge carriers orthogonal to the surface of the substrate along the FIN height. A vertical transport field effect transistor, VTFET, wherein the FIN is configured to transport charge carriers orthogonal to the surface of the substrate along the FIN height, provides scaling advantages that are not available in other FET structures, for example such as lateral FETs or FINFETs. In addition, providing a first n-type structure oriented in a first plane direction relative to the substrate and a first p-type structure oriented in a second plane direction relative to the substrate provides that the optimum orientation for charge carrier mobility in both the p and n type structures is achieved. The plane describes the crystal plane of the material, typically Si, from which the n and p type structures are fabricated. Where both the n-type and the p-type structures are oriented in the same direction, optimum mobility in at least one of the structures would not be achieved.

The first plane direction may be oriented 45 degrees relative to the second plane direction. This orientation provides for optimizing charge carrier mobility in the p and n type devices.

The first n-type FET structure may comprise an NMOS transistor; and the first p-type FET structure may comprise a PMOS transistor. This provides for enhanced charge carrier mobility in PMOS and NMOS structures and further provides for integration with existing PMOS and NMOS technology.

The substrate of the VTFET may be a (100) silicon substrate. The FIN of the PMOS transistor may be oriented in a <110> plane direction, while the FIN of the NMOS transistor may be oriented in a <100> plane direction. This configuration of orientations between the silicon substrate and PMOS and NMOS transistors provides for optimized charge carrier mobility in the channels of the PMOS and NMOS transistors.

The NMOS transistor and the PMOS transistor of the VTFET may be arranged in a vertical stack configuration relative to the surface of the substrate to form a vertical transport complementary FET, (VTCFET). Integration of NMOS and PMOS in this stacked manner provides for efficient use of circuit area and further provides an enhanced CMOS structure with optimized mobility in both P and N channels.

The stacked structure may be tailored to meet the requirements and constraints of a given circuit requirement.

The n-type FET structure and p-type FET structure of the VTFET may comprise: a FIN width, W, and a FIN length, L, the FIN length being adjustable to provide a predefined effective channel width, W_{eff}, for the channel. Adjusting the FIN length in this manner allows for a desired W_{eff} to be achieved. W_{eff}=2L+2W, as such wherein a particular W_{eff} is required to meet a circuit specification or constraint, L may be adjusted such that the derived W_{eff} is achieved. This provides a large degree of flexibility in circuit design and fabrication as L may be adjusted in an “analog” manner to achieve a given effective channel width, W_{eff}, with W_{eff} being a key indicator of device performance.

Each of the n-type FET structure and the p-type FET structure of the VTFET may further comprise a gate structure, the gate structure surrounding the channel. Such a structure provides for a gate all around, GAA, structure which maximizes the amount of gate surface available for charge carrier transport in the device.

A method of fabricating a vertical transport field effect transistor (VTFET), the method comprising forming a plurality of FET structures on a substrate; the plurality of FET structures comprising: a first n-type FET structure oriented in a first plane direction relative to the substrate; and a first p-type FET structure oriented in a second plane direction relative to the substrate; wherein the first n-type FET structure and the first p-type FET structure each comprises a channel comprising a FIN having a FIN height, H, wherein H defines the FIN height orthogonal to a surface of the substrate, each FIN being configured to transport charge carriers orthogonal to the surface of the substrate along the FIN height. Fabricating a VTFET in this manner provides for enhanced performance in the resulting device.

In the method, the first plane direction may be oriented 45 degrees relative to the second plane direction. This orientation provides for optimizing charge carrier mobility in the p and n type devices.

The first n-type FET structure may comprise an NMOS transistor; and the first p-type FET structure may comprise a PMOS transistor. This provides for enhanced charge carrier mobility in PMOS and NMOS structures and further provides for integration with existing PMOS and NMOS technology.

The substrate may be a (100) silicon substrate. The FIN of the PMOS transistor may be oriented in a <110> plane direction. The FIN of the NMOS transistor may be oriented in a <100> plane direction. This configuration of orientations between the silicon substrate and PMOS and NMOS transistors provides for optimized charge carrier mobility in the channels of the PMOS and NMOS transistors.

The NMOS transistor and the PMOS transistor may be arranged in a vertical stack configuration relative to the surface of the substrate to form a vertical transport complementary FET, (VTCFET). Fabrication of NMOS and PMOS in this stacked manner provides for efficient use of circuit area and further provides an enhanced CMOS structure with optimized mobility in both P and N channels.

As such a degree of adjustability is provided in the method such that structures can be arranged in the most suitable manner to meet a given circuit requirement.

The method may further comprise defining a FIN width, W, and a FIN length, L, the FIN length being adjustable to provide a predefined effective channel width, W_{eff}, for the channel. Adjusting the FIN length in this manner allows for a desired W_{eff} to be achieved. As noted, wherein a particular W_{eff} is required to meet a circuit specification or constraint, L may be adjusted such that the derived W_{eff} is achieved. This provides a great degree of flexibility in circuit design and fabrication as L may be adjusted in an “analog” manner to achieve a given W_{eff}.

The method may further comprise forming a gate structure, the gate structure surrounding the channel. Such an arrangement provides for a GAA structure.

W_{eff} is defined by an equation W_{eff}=2L+2W. The present disclosure provides an arrangement where the W_{eff} is adjustable or tunable by changes in the FIN length, L.

An effective length of the gate structure, L_{eff}, is defined based on the FIN height. As the FIN height and the gate length are in the vertical direction orthogonal to the surface of the substrate, this provides a greater degree of control over L_{eff} as the FIN height may be defined by epitaxial growth during fabrication.

### BRIEF DESCRIPTION OF THE DRAWINGS

FIG. 1 is a representation of a FINFET structure according to the prior art.

FIG. 2 is a representation of a VTFET structure according to the prior art.

FIG. 3A is a representation of an orientation of an N-Type structure on a substrate surface.

FIG. 3B is a representation of an orientation of a P-Type structure on a substrate surface.

FIG. 4A is a top down representation of a VTFET structure with FIN length L1.

FIG. 4B is a top down representation of a VTFET structure with FIN length L2.

FIG. 4C is a top down representation of a VTFET structure with FIN length L3.

FIG. 5A, FIG. 5B and FIG. 5C are representations of alternative VTFET structures according to the present invention.

FIG. 6A, FIG. 6B and FIG. 6C are representations of alternative VTFET structures according to the present invention.

FIG. 7A, FIG. 7B and FIG. 7C are a cross sectional representation of the VTFET structures of FIG. 4A, FIG. 4B and FIG. 4C.

FIG. 8 shows the result of FIN patterning used in the fabrication of a VTFET structure according to the invention.

FIG. 9 shows a well patterning step used in the fabrication of a VTFET structure according to the invention.

FIG. 10 shows an oxide layer deposition and chemical mechanical polishing step used in the fabrication of a VTFET structure according to the invention.

FIG. 11 shows an etching step used in the fabrication of a VTFET structure according to the invention.

FIG. 12 shows a patterning step used in the fabrication of a VTFET structure according to the invention.

FIG. 13 shows a gate formation step used in the fabrication of a VTFET structure according to the invention.

FIG. 14 shows a well formation step used in the fabrication of a VTFET structure according to the invention.

FIG. 15 shows an oxide layer deposition and chemical mechanical polishing step used in the fabrication of a VTFET structure according to the invention.

FIG. 16 shows an epi layer deposition and contact formation step used in the fabrication of a VTFET structure according to the invention.

FIG. 17 is a representation of vertical transport complementary FET (VTCFET) structure according to the present invention.

FIG. 18 is a representation of vertical transport complementary FET (VTCFET) structure according to the present invention.

### DETAILED DESCRIPTION

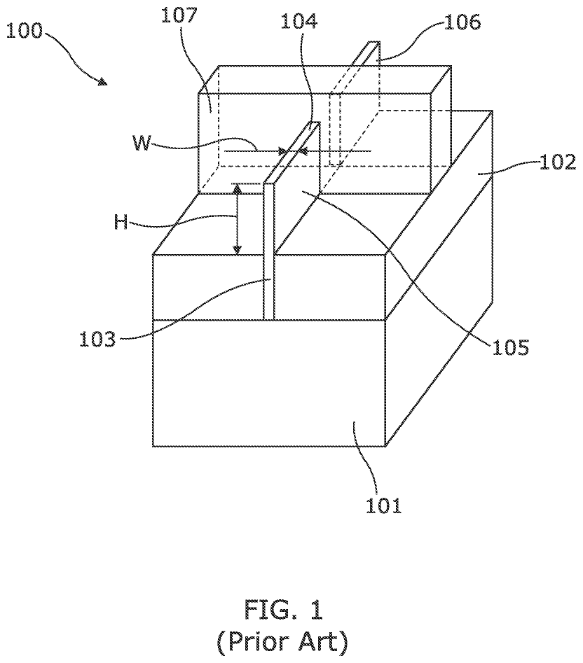

The invention will now be described with reference to the accompanying figures. FIG. 1 is a representation of a FINFET structure 100 according to the prior art.

The structure 100 comprises a silicon substrate 101 onto which an oxide layer 102 is formed. A 3D FIN structure 103 forms a transport channel 104 and transports charge carriers from the source 105 to the drain 106 through a gate structure 107. It is noted that the direction of travel of the charge carriers is parallel to the substrate surface. FINFET transistors comprising 3D structures such as that displayed in FIG. 1 can offer improved charge carrier transport over planer devices and further provide the opportunity to increase the amount of effective width (W_{eff}) available in a given device area. W_{eff} effectively increases the channel region of device available for transport of electrons or holes and thus is a key indicator of device performance. So whilst providing an improvement over previous planer structures, FINFETs themselves present some disadvantages. As already noted, such structures are reaching their scaling limits. In order to maintain reliable functionality, the FIN elements of FINFET structures must maintain a digital width, W, rather than an analog width for device drive ability matching. In addition, the FIN height H in FINFET is fixed as increases in H in such structures lead to higher device aspect ratios and less process margin. Furthermore, H in a FIN structure is fixed for all FINFETs. As such, an individual FINFET H may not be adjusted to adjust W_{eff}.

As such, to increase W_{eff} in such devices, a number of additional FINs may be added. For such a FINFET device W_{eff}=N*(W_{eff} Fin) where N is the number of FINs and W_{eff}Fin is the effective width of a FIN. As such, FINFET W_{eff} is “quantized” and may only be increased by a set factor, i.e., x2, x3 etc. depending on the number of FINs. Furthermore, increasing the number of FINs inevitably increases the dimensions of the overall device.

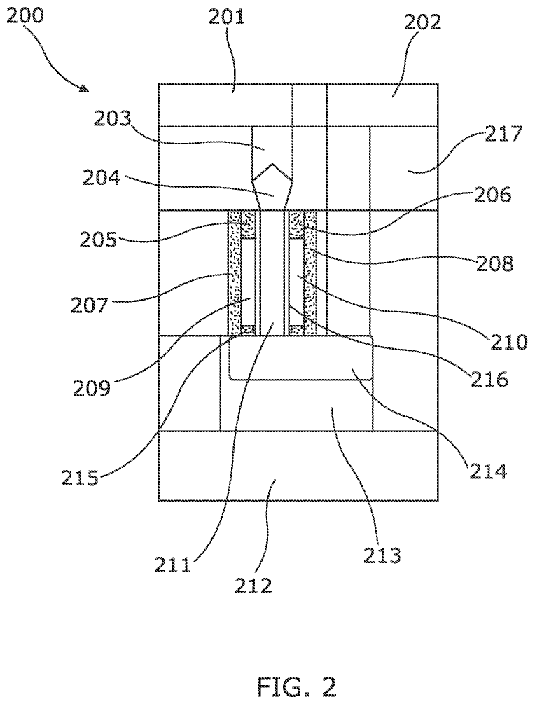

FIG. 2 is a representation of a vertical transport FET (VTFET) structure 200 according to the prior art. With reference to FIGS. 2, 201 and 202 are metal zero layers. These may be fabricated from, for example, copper. 203 is a drain contact and may be fabricated from, for example tungsten or cobalt. 204 is an epi layer used to form a drain, which for an NMOS device may be fabricated from, for example Si or for a PMOS device from SiGe. 205 and 206 are top spacers. These serve to isolate the gate and contact and may be fabricated for example, from Silicon Nitride, SiN. 215 is a bottom spacer. Again, this serves to isolate the gate and contact. 207 and 208 are cap layers for the gate. These may be formed from an oxide layer or from SiN. 217 is an oxide layer. 209 and 210 form the metal gate structure while 216 is a high-k dielectric layer. 211 is the channel structure comprising a FIN which corresponds in function of the FIN of the FINFET structure. The VTFET comprise a FIN having a height H, wherein H defines a FIN height orthogonal to the substrate surface, the FIN being configured to transport charge carriers (electrons or holes) orthogonal to the substrate surface along the FIN height. Note that in this vertical structure, the FIN height, H, the distance bridged by the FIN between the source and drain epi regions is defined by a material height. This distance defines the effective gate length, gate L_{eff}. As such, the height and thus the effective gate length may be defined as a layer by layer height using an epitaxial process. This is more accurate than the photolithographic process used to define the effective gate length in a FINFET structure. 212 is the substrate material. 213 is the well, which for an NMOS device will be a P-well while for a PMOS device will be an N-Well. 214 is a bottom side epi layer used to form a source. This epi layer may further provide stress and strain into the channel region to increase mobility in the channel. The stress and strain may be provided by a slight mismatch between the atomic lattice structure of the epi layer and the lattice structure of the channel. In an NMOS device, tensile stress is introduced to the channel, while for PMOS compressive stress is introduced to the channel.

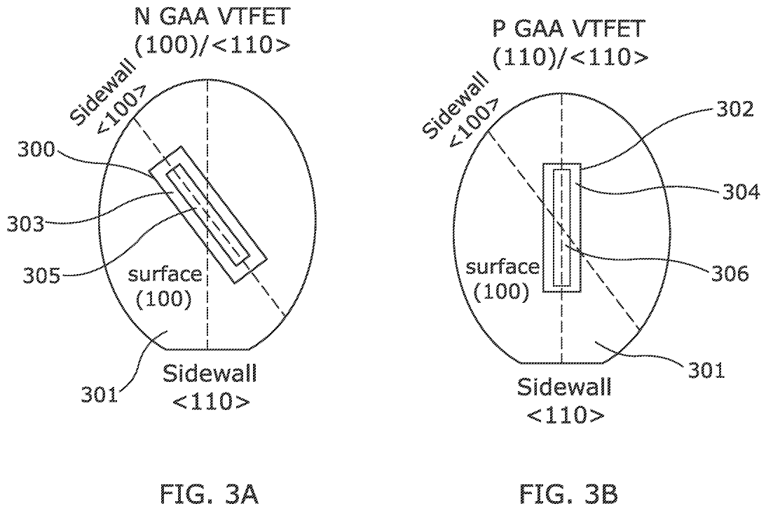

FIG. 3A is a representation of an orientation of an N-Type structure 300 on a substrate surface 301 while FIG. 3B is a representation of an orientation of a P-Type structure 302 on the substrate surface 301. In both FIGS. 3A and 3B, the structure is viewed from a top down perspective onto the substrate surface 301. The gate 303, 304 and channel 305, 306 structures of FIG. 3A and FIG. 3B may correspond to those of FIG. 2. The substrate 301 is a (100) silicon substrate. Used in this context, (100) is an indication of the crystal plane of the Si surface using Miller indices. These indices are used to indicate the orientation of Si crystalline structure. The orientation results from the growth direction used for the silicon ingot from which the Si wafer was sliced.

As such, in the example provided, the Si wafer has been fabricated to present a (100) orientation surface onto which additional structures may be fabricated. The n-type device is fabricated in the <100> plane direction while the p-type device is fabricated 45 degrees relative to a <100> Si plane direction in a <110> plane direction. The channel plane direction relative to the Si wafer may be changed by rotating the wafer flat or notch through 45 degrees during fabrication.

The n-type device 300 of FIG. 3A is shown as an NMOS gate all around (GAA) VTFET. In the GAA structure, the gate 303 is seen to surround the channel on four sides, i.e., “all around”. This differs from the FINFET structure of FIG. 1 wherein the gate covers three sides of the channel only, with the gate being interrupted by the substrate on the fourth channel side. The channel of the n-type structure 300 shown may be a channel of an NMOS transistor. With reference to FIG. 3A, it can be seen that the channel 305 of the NMOS transistor may be oriented in the (100) surface plane relative to the substrate surface.

The p-type device 302 of FIG. 3B is shown as a PMOS gate all around (GAA) VTFET. Again, the gate 304 is seen to surround the channel 306 on four sides. The channel of the p-type structure 302 may thus be a channel of a PMOS transistor. With reference to FIG. 3B, it can be seen that the channel 306 of the PMOS transistor is oriented in the (110) surface plane relative to the substrate surface. As such, this has the effect that the channels 305, 306 of the NMOS and PMOS structures are oriented at 45 degrees relative to each other. It is noted that orientation of the NMOS and PMOS structures in the configuration described provides for optimization of electron mobility in the NMOS structure and optimization of hole mobility in the PMOS structure. In particular, it is noted that providing the PMOS structure in the (110) surface plane orientation leads to considerably enhanced charge carrier mobility.

A vertical transport field effect transistor (VTFET) may thus be provided comprising a plurality of FET structures such as the GAA VTFET structures described on a substrate. The plurality of FET structures may comprise a first n-type structure oriented in a first plane direction relative to the substrate and a first p-type structure oriented in a second plane direction relative to the substrate.

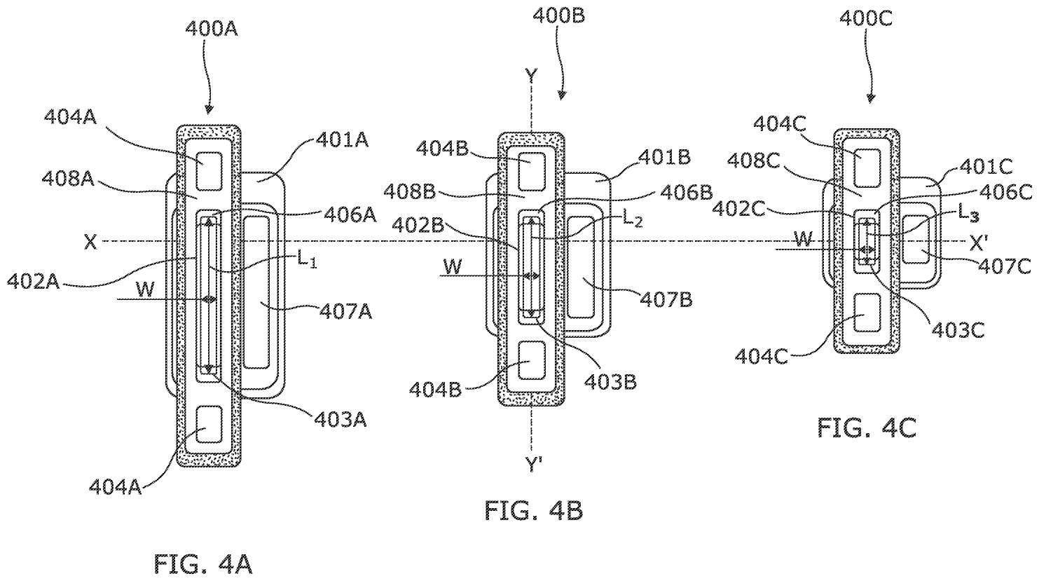

The n-type structure and p-type structure of the VTFET may comprise a FIN pattern area with a FIN width, W, and a FIN length, L, the FIN length being adjustable to provide a predefined effective channel width, W_{eff}, for the channel. Examples of VTFET structures of different FIN lengths are shown in FIGS. 4A, 4B and 4C. FIG. 4A is a top down representation of a VTFET structure 400A with FIN length L1. FIG. 4B is a top down representation of a VTFET structure 400B with FIN length L2. FIG. 4C is a top down representation of a VTFET structure 400C with FIN length L3.

Each of the structures of FIGS. 4A, 4B and 4C is shown fabricated on a bottom silicon layer 401A, 401B, 401C. The channel 402A, 402B, 402C comprising the FIN structure 403A, 403B, 403C is shown. Located on the top of channel 402A, 402B, 402C is drain contact. A gate oxide 406A, 406B, 406C is shown around the channel region. Two gate contacts 404A, 404B and 404C are shown on each structure as well as a single source contact 407A, 407B, 407C. The gate structure 408A, 408B, 408C is shown as a GAA type gate structure. Note that the channel is again surrounded by the gate such that all four channel sides are exposed to the gate. The W_{eff} of the channel is defined by the equation W_{eff}=2L+2W. Accordingly, the W_{eff} of the channel in FIG. 4A is W_{eff}=2L1+2W, the W_{eff} of the channel in FIG. 4B is W_{eff}=2L2+2W, the W_{eff} of the channel in FIG. 4C is W_{eff}=2L3+2W. As such, a large degree of flexibility is provided at the design and fabrication stage to adjust the FIN length, L, according to a desired specification. In this manner, analogue “tuning” of the W_{eff} may be provide by adjusting the FIN L until a desired W_{eff} criteria is met. FINFET solutions do not provide for such tunable adjustment and the W_{eff} may only be incremented or decremented by a set or quantized amount dependent on the number of FINs being used.

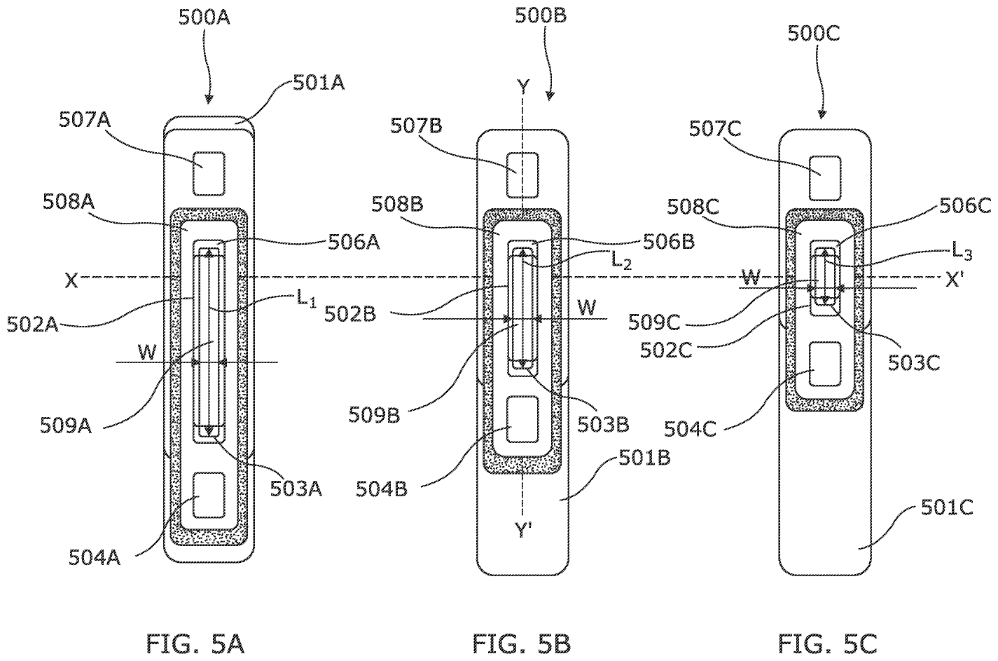

FIG. 5A, FIG. 5B and FIG. 5C are representations of an alternative VTFET structure to that of FIG. 4A, FIG. 4B and FIG. 4C. FIG. 5A is a top down representation of a VTFET structure 500A with FIN length L1. FIG. 5B is a top down representation of a VTFET structure 500B with FIN length L2. FIG. 5C is a top down representation of a VTFET structure 500C with FIN length L3. Each of the structures of FIGS. 5A, 5B and 5C is shown fabricated on a bottom silicon layer 501A, 501B, 501C. The channel 502A, 502B, 502C composing the FIN structure 503A, 503B, 503C is shown. A gate oxide 506A, 506B, 506C is shown around the channel region. In this alternative, a single gate contact 504A, 504B, 504C is provided as compared to the two gate contacts of FIG. 4A, FIG. 4B and FIG. 4C as well as a single source contact 507A, 507B, 507C. 509A, 509B and 509C are drain contacts. The gate structure 508A, 508B, 508C is shown. Note that the channel is again surrounded by the gate such that all four channel sides are exposed to the gate. Once again, the W_{eff} of the channel is defined by the equation W_{eff}=2L+2W. Accordingly, the W_{eff} of the channel in FIG. 5A is W_{eff}=2L1+2W, the W_{eff} of the channel in FIG. 5B is W_{eff}=2L2+2W, the W_{eff} of the channel in FIG. 5C is W_{eff}=2L3+2W.

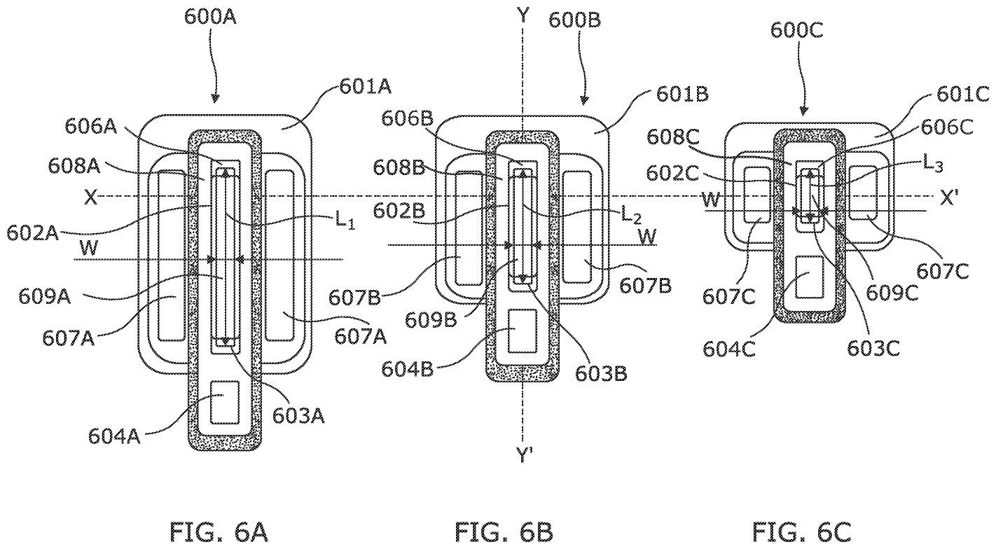

FIG. 6A, FIG. 6B and FIG. 6C are representations of alternative VTFET structures to that of FIG. 4A, FIG. 4B and FIG. 4C. FIG. 6A is a top down representation of a VTFET structure with FIN length L1. FIG. 6B is a top down representation of a VTFET structure with FIN length L2. FIG. 6C is a top down representation of a VTFET structure with FIN length L3. Each of the structures of FIGS. 6A, 6B and 6C is shown fabricated on a bottom silicon layer 601A, 601B, 601C. The channel composing the FIN structure 603A, 603B, 603C is shown. A gate oxide 606A, 606B, 606C is shown around the channel region. In this alternative, two source contacts 607A, 607B, 607C are provided as compared to single source contact of FIG. 4A, FIG. 4B and FIG. 4C. In this alternative, a single gate contact 604A, 604B, 604C is provided. 609A, 609B and 609C are drain contacts. The gate structure 608A, 608B, 608C is shown. Note that the channel is again surround by the gate such that all four channel sides are exposed to the gate. Once again, the W_{eff} of the channel is defined by the equation W_{eff}=2L+2W. Accordingly, the W_{eff} of the channel in FIG. 6A is W_{eff}=2L1+2W, the W_{eff} of the channel in FIG. 6B is W_{eff}=2L2+2W, the W_{eff} of the channel in FIG. 6C is W_{eff}=2L3+2W.

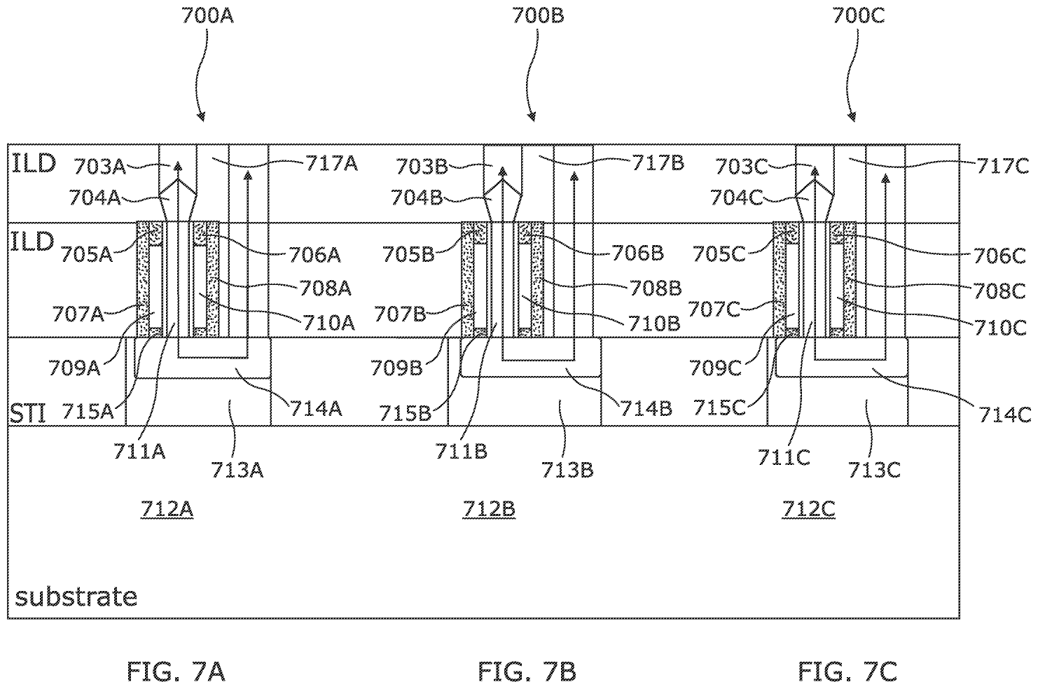

FIG. 7A, FIG. 7B and FIG. 7C provide a cross sectional representation of the VTFET structure 700A, 700B, 700C of FIG. 4A, FIG. 4B and FIG. 4C. 703A, 703B and 703C are drain contacts. 704A, 704B, 704C are epi layers for the drain. 705A, 705B and 705C, 706A, 706B and 706C are top spacers. 715A, 715B and 715C are bottom spacers. 707A, 707B and 707C and 708A, 708B and 708C are cap layers for the gate. 717A, 717B and 717C is an oxide layer. 709A, 709B, 709C, 710A, 710B and 710C form the gate structure. 711A, 711B and 711C are the channels. 712A, 712B and 712C is the substrate material. 713A, 713B and 713C are the wells, which for an NMOS device will be a P-well while for a PMOS device will be an N-Well. 714A, 714B and 714C are the bottom side epi layers used to form the source.

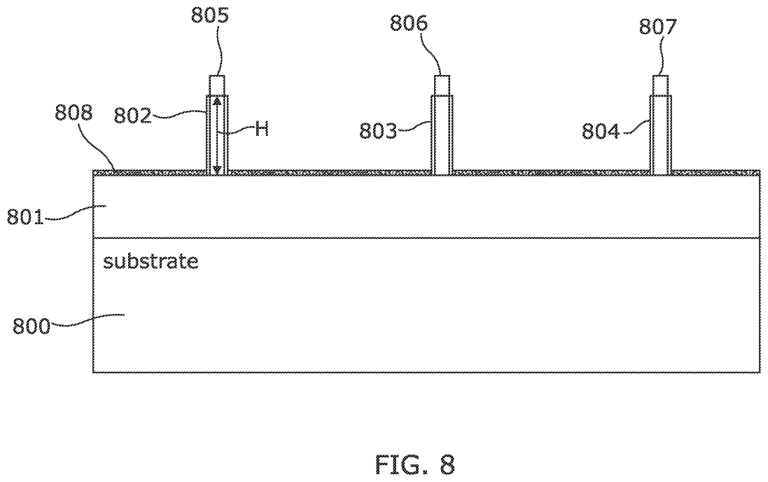

The fabrication of the structures as per those shown in FIGS. 4A-4C and 7A-7C will now be described. FIG. 8 shows the result of FIN patterning used in the fabrication of a VTFET structure according to the invention. A well 801 is formed on the substrate 800 by introducing dopants into the substrate. The substrate may be a (100) silicon substrate. A P-well may be formed for an NFET device while an N-well may be formed for a PFET device. Channel material may be etched from the substrate or deposited to provide a channel FIN structure to a specified W, L and H. A gate oxide 802, 803, 804 is also provided. The FIN has a height H, wherein H defines a FIN height orthogonal to the substrate surface, the FIN being configured to transport charge carriers orthogonal to the substrate surface along the FIN height. Note that as described, the channel of a PMOS transistor may be oriented in the <110> plane direction relative to the substrate. The channel of an NMOS transistor may be oriented in the <100> plane direction relative to the substrate.

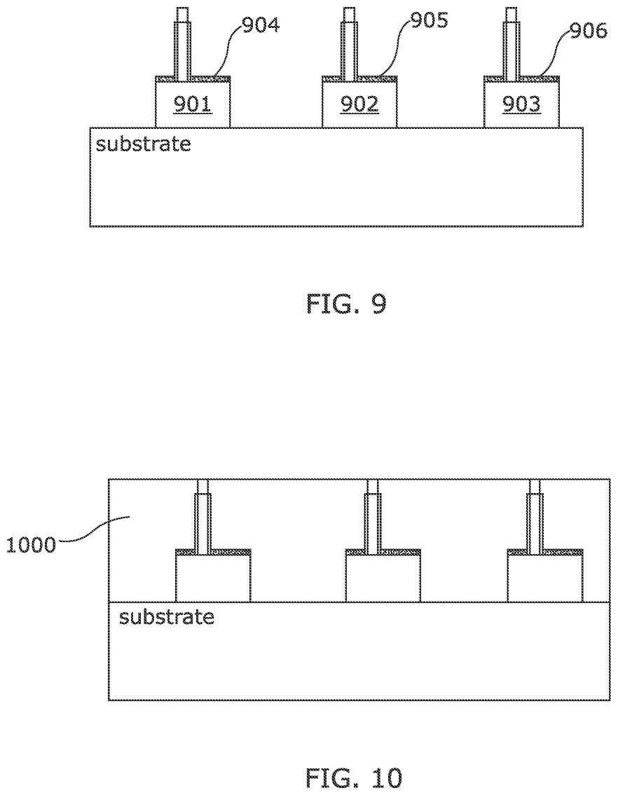

An oxide layer or Silicon Nitride, SiN, layer 805, 806, 807 and 808 is then deposited and subsequently etched to remove oxide or SiN from the FIN sidewall. Well patterning may then be performed as shown in FIG. 9. This provides for a bottom well 901, 902, 903 and a bottom spacer 904, 905, 906. The patterning is performed by etching away areas of the well layer to provide defined well structures 901, 902, 903. FIG. 10 shows deposition of an oxide layer 1000. Chemical mechanical polishing (CMP) is then performed.

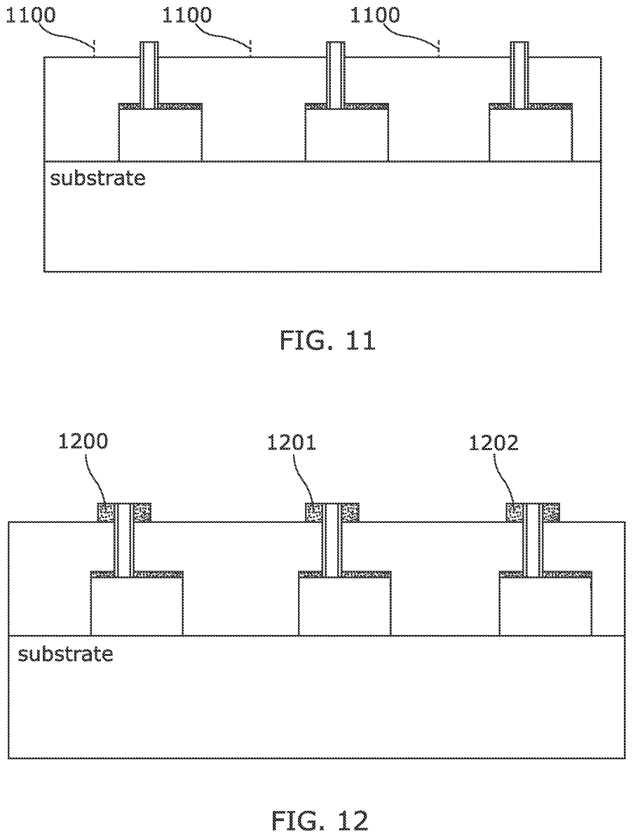

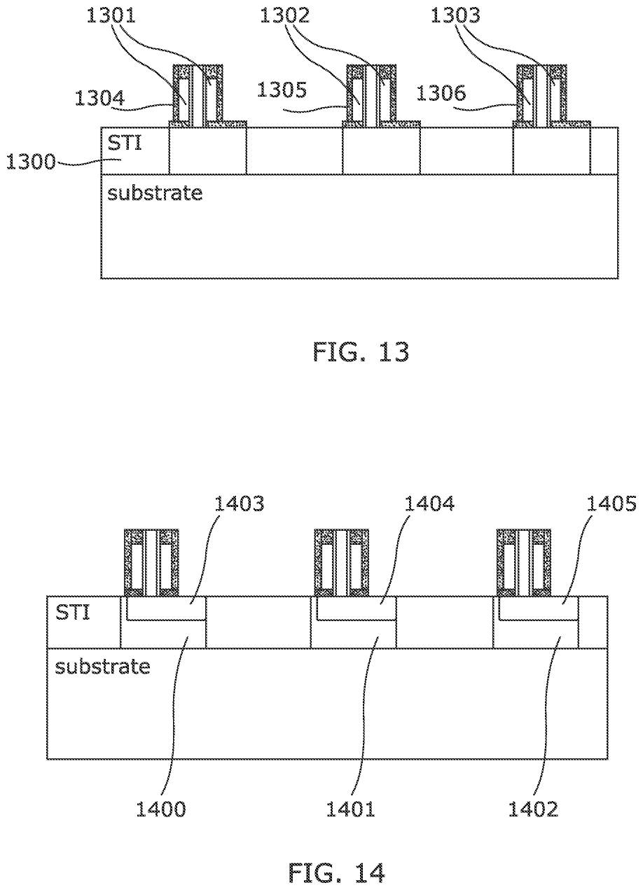

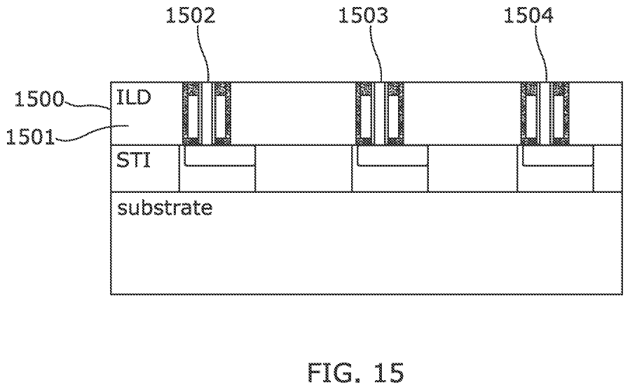

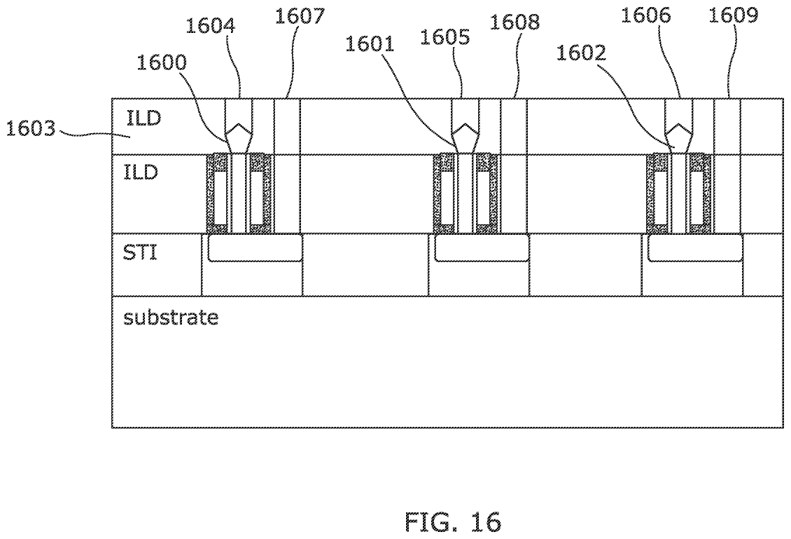

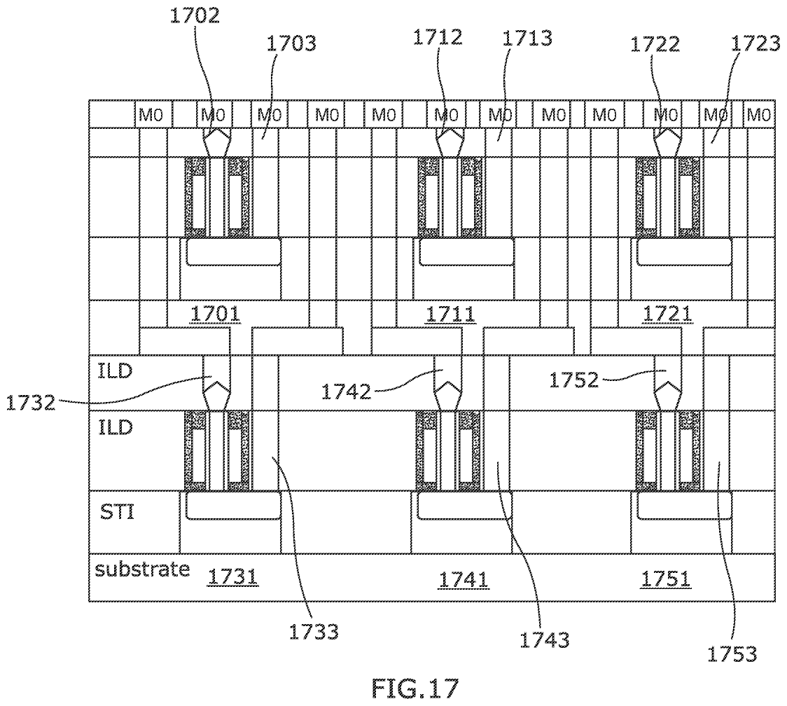

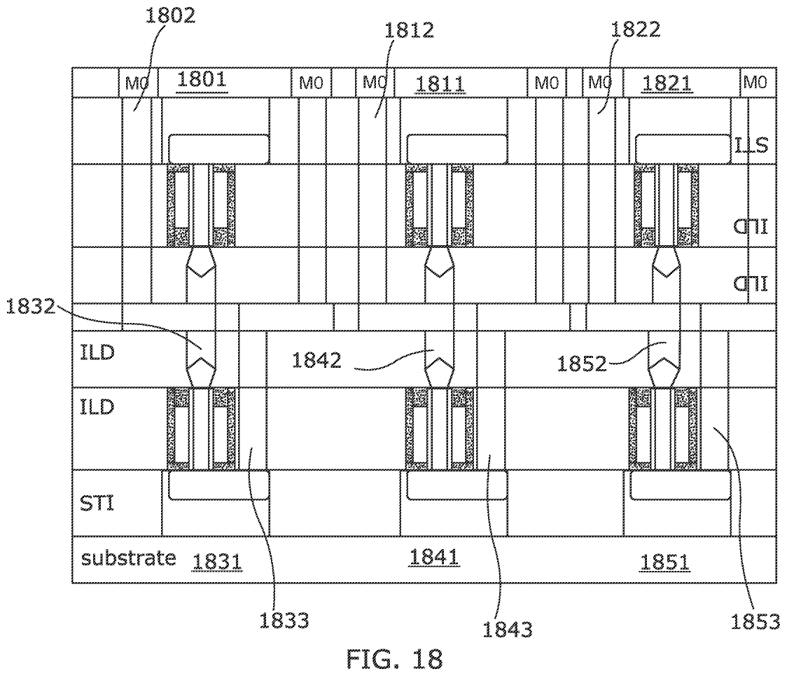

Etching is performed to provide an oxide recess 1100 as shown in FIG. 11. A layer of SiN is then deposited. This layer is patterned and then etched back to form the top spacer 1200, 1201, 1202 in FIG. 12. Next, in FIG. 13, oxide is recessed to form a Shallow Trench Isolation layer, STI, and the metal gate 1301, 1302 and 1303 is formed. The metal gate is then patterned. The gate structure is formed to surround the channel sidewall about the FIN width and the FIN length to form a GAA structure as previously described. A SiN film is deposited and etched back to form the spacer 1304, 1305, 1306. In FIG. 14, patterning and recessing is performed to provide a bottom well 1400, 1401, 1402 for the epi layer 1403, 1404, 1405. The epi layer forms the source. The epi layer is deposited and provides strain into the channel due to lattice mismatch between the epi layer and the channel. In FIG. 15, an oxide layer 1500 is deposited and chemical mechanical polishing is performed. This forms the interlayer dielectric ILD 1501. Subsequently, a channel recess 1502, 1503, 1504 is formed. In FIG. 16, an epi top layer 1600, 1601, 1602 is grown or deposited to form the drain. A further oxide deposit and chemical mechanical polishing is performed to form a second interlayer dielectric, ILD 1603. As such, a source structure is formed by deposition of a first epitaxial layer at a first end of the FIN proximal to the substrate surface; and a drain structure is formed by deposition of a second epitaxial layer at a second end of the FIN distal to the substrate surface. Contacts 1604, 1605, 1606 and 1607, 1608, 1609 are then formed for the drain and source. A voltage may be applied across the contacts for the device to function. The device as shown may be placed or “stacked” above another such device to form the vertical transport complementary FET as described herein. FIG. 17 and FIG. 18 show such vertical transport complementary FET structures.

FIG. 17 is a representation of vertical transport complementary FET structure. Such a structure provides for an NMOS transistor and a PMOS transistor to be arranged in a vertical stack configuration relative to the substrate surface to form a vertical transport complementary FET, (VTCFET).

The NMOS transistor of the VTFET may be arranged below the PMOS transistor in the stacked configuration. The NMOS transistor of the VTFET may be arranged above the PMOS transistor in the stacked configuration. For example, in the representation of FIG. 17, the structures 1701, 1711 and 1721 may be configured (i.e., doped or work function adjusted accordingly to provide n-type functionality) to be NMOS transistors while the structures 1731, 1741 and 1751 may be configured (i.e., doped or work function adjusted accordingly to provide p-type functionality) to be PMOS transistors. The reverse may also be provided where the structures 1701, 1711, 1721 are configured to be PMOS transistors and the structures 1731, 1741, 1751 are configured to be NMOS transistors. Stacking and integrating the PMOS and NMOS transistors thus provides for the VTCFET structure. Thus, the performance benefits of the vertical structures as described herein can be provided in a CMOS device to take advantage of the existing benefits of CMOS vs NMOS/PMOS, such as reduced power consumption and enhanced functionality. The arrangement of FIG. 17 shows 6 FET structures 1701, 1711, 1721, 1731, 1741 and 1751 sharing a common substrate. Each of the FET comprises features as described with respect to FIGS. 4A-4C and FIGS. 7A-7C. As such, these features will not be described further here. Attention is drawn however to the contact structures of the FETs. FET 1701 comprises drain contact 1702 and source contact 1703. FET 1711 comprises drain contact 1712 and source contact 1713. FET 1721 comprises drain contact 1722 and source contact 1723. FET 1731 comprises drain contact 1732 and source contact 1733. FET 1741 comprises drain contact 1742 and source contact 1743. FET 1751 comprises drain contact 1752 and source contact 1753. Each contact comprises a metal layer surface contact (MO), thus resulting in 12 metal contacts in total. Such an arrangement provides for effective stacking of FET structures. An alternative arrangement however can provide for reduced metal layer surface contacts.

FIG. 18 is an alternative arrangement of vertical transport complementary FET structure to that of FIG. 17. The arrangement of FIG. 18 shows 6 FET structures 1801, 1811, 1821, 1831, 1841 and 1851 sharing a common substrate. Again, each of the FET comprises features as described with respect to FIGS. 4A-4C and FIGS. 7A-7C. As such, these features will not be described further here. Attention is drawn however to the contact structures of the FETs. FET 1801 comprises drain contact 1802 and source contact (not visible in the cross section of FIG. 18). FET 1811 comprises drain contact 1812 and source contact (not visible in the cross section of FIG. 18). FET 1821 comprises drain contact 1822 and source contact (not visible in the cross section of FIG. 18). FET 1831 comprises drain contact 1832 and source contact 1833. FET 1841 comprises drain contact 1842 and source contact 1843. FET 1851 comprises drain contact 1852 and source contact 1853. Note the inversion of 1801, 1811 and 1821 with respect to 1831, 1841 and 1851 (and in comparison with 1701, 1711 and 1721) allows the drain contacts of 1801 and 1831 to be connected to a shared metal contact, MO. Furthermore, the drain contacts of 1811 and 1841 are connected to a shared metal contact and the drain contacts of 1821 and 1851 are connected to a shared metal contact. This sharing of the metal contacts for drain structures as shown in FIG. 18 provides for 9 metal layer surface contacts (MO), comprising 3 shared drain contacts and 6 source contacts (with 3 of the source contacts not being visible in FIG. 18). This compares to the 12 metal layer surface contacts of FIG. 17.

Even though particular combinations of features are recited in the claims and/or disclosed in the specification, these combinations are not intended to limit the disclosure of various aspects. In fact, many of these features may be combined in ways not specifically recited in the claims and/or disclosed in the specification. Although each dependent claim listed below may directly depends on only one claim, the disclosure of various aspects includes each dependent claim in combination with every other claim in the claim set. A phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

No element, act, or instruction used herein should be construed as critical or essential unless explicitly described as such. Also, as used herein, the articles “a” and “an” are intended to include one or more items, and may be used interchangeably with “one or more.” Furthermore, as used herein, the terms “set” and “group” are intended to include one or more items (e.g., related items, unrelated items, a combination of related and unrelated items, and/or the like), and may be used interchangeably with “one or more.” Where only one item is intended, the phrase “only one” or similar language is used. Also, as used herein, the terms “has,” “have,” “having,” and/or the like are intended to be open-ended terms. Further, the phrase “based on” is intended to mean “based, at least in part, on” unless explicitly stated otherwise.

1. A method of wireless communication performed by a user equipment (UE), the method comprising:
receiving, from a network node, a grant message indicating a set of sidelink resources and indicating a number of subgroups of sidelink resources in the set of sidelink resources; and
transmitting multiple unicast messages via multiple subgroups of the subgroups of sidelink resources in the set of sidelink resources, the multiple subgroups of the sidelink resources based on the number of subgroups of sidelink resources.

2. The method of claim 1, further comprising
configuring the multiple subgroups of the set of sidelink resources; and
transmitting the multiple unicast messages via the multiple subgroups includes transmitting, via each subgroup of the multiple subgroups, a unicast message of the multiple unicast messages.

3. (canceled)

4. The method of claim 1, further comprising:
determining, based on the grant message, the set of sidelink resources; and
splitting the set of sidelink resources into the multiple subgroups.

5. The method of claim 1, further comprising:
splitting the set of sidelink resources into the multiple subgroups, wherein the set of sidelink resources are split based on a receive (RX) UE buffer status report and channel state information of an RX UE channel.

6. The method of claim 1, further comprising:
scheduling the multiple unicast messages; and
wherein transmitting the multiple unicast messages comprises:
transmitting, to a first receive (RX) UE, a first unicast message of the multiple unicast messages via a first subgroup of the multiple subgroups; and
transmitting, to a second RX UE, a second unicast message of the multiple unicast messages via a second subgroup of the multiple subgroups;
receiving a first ACK/NACK message from the first RX UE responsive to the first unicast message; and
receiving a second ACK/NACK message from the second RX UE responsive to the second unicast message.

7. (canceled)

8. The method of claim 1, further comprising:
generating a buffer status for each of one or more receive (RX) UEs; and
transmitting a sidelink buffer status report (BSR) to the network node to request sidelink resources.

9. The method of claim 8, further comprising combining the buffer status of multiple RX UEs to generate the sidelink BSR.

10. The method of claim 1, further comprising transmitting a feedback message to the network node, wherein the feedback message comprises an ACK/NACK message, and wherein the ACK/NACK message includes an ACK/NACK indicator for each subgroup of the multiple subgroups.

11. The method of claim 10, wherein:
the feedback message is responsive to the grant message;
the feedback message is a single feedback message; or
a combination thereof.

12. The method of claim 10, wherein the ACK/NACK indicator includes one or more bits.

13. The method of claim 10, wherein wherein the ACK/NACK indicator includes multiple bits, the method further comprising:
determining an amount of resources to be requested from the network node; and
determining a value of the multiple bits based on the amount.

14. The method of claim 13, further comprising:
determining a maximum number of subgroups into which the set of sidelink resources are splitable; and
receiving an upper layer message;
wherein the maximum number of subgroups is determined based on the upper layer message.

15. A user equipment (UE) comprising:
at least one processor; and
a memory coupled with the at least one processor and storing processor-readable code that, when executed by the at least one processor, is configured to cause the UE to:
receive, from a network node, a grant message indicating a set of sidelink resources and indicating a number of subgroups of sidelink resources in the set of sidelink resources; and
transmit multiple unicast messages via multiple subgroups of the subgroups of sidelink resources in the set of sidelink resources, the multiple subgroups of the sidelink resources based on the number of subgroups of sidelink resources.

16. The UE of claim 15, wherein the processor-readable code that, when executed by the at least one processor, is further configured to cause the UE to:
generate a feedback message; and
transmit the feedback message to the network node.

17. The UE of claim 16, wherein the feedback message includes a number of ACK/NACK indicators.

18. The UE of claim 16, wherein the feedback message includes an ACK/NACK indicator for each subgroup of the multiple subgroups.

19. The UE of claim 16, wherein the feedback message includes an ACK/NACK indicator for each subgroup of a maximum number of subgroups, and wherein the set of sidelink resources are splitable into a maximum number of subgroups.

20. The UE of claim 16, wherein the feedback message indicates, for the number of one or more subgroups, a number of ACKs, a number of NACKS, or both.

21. The UE of claim 16, wherein the feedback message includes an ACK/NACK indicator, and the ACK/NACK indicator includes multiple bits.

22. The UE of claim 21, wherein the processor-readable code that, when executed by the at least one processor, is further configured to cause the UE to:
determine a value of the multiple bits; and
determine an amount of resources requested by the UE based on the value.

23. The UE of claim 15, wherein the processor-readable code that, when executed by the at least one processor, is further configured to cause the UE to determine, based on a hybrid automatic repeat request (HARQ) process identity (ID) field of the grant message, a HARQ ID of a first subgroup of the set of sidelink resources.

24. (canceled)

25. The UE of claim 15, wherein the processor-readable code that, when executed by the at least one processor, is further configured to cause the UE to:
determine the number of one or more subgroups of the set of sidelink resources, the number of one or more subgroups of the set of sidelink resources is less than or equal to a maximum number of subgroups the set of sidelink resources is splitable into; and
receive a radio resource control (RRC) message that indicates the maximum number of subgroups.

26. The UE of claim 15, wherein a new data indicator (NDI) control of the grant message is used for multiple subgroups.

27. The UE of claim 15, wherein each subgroup is associated with a new data indicator (NDI) control of the grant message.

28. The UE of claim 15, wherein the processor-readable code that, when executed by the at least one processor, is further configured to cause the UE to:
transmit a feedback message to the network node; and
wherein:
the feedback message includes a number of ACK/NACK indicators; or
the feedback message includes an ACK/NACK indicator for each subgroup.

29. The UE of claim 15, wherein the grant message is a single grant message, and wherein the grant message includes a single DCI.

30. (canceled)

31. The method of claim 1, wherein the number of subgroups of sidelink resources in the set of sidelink resources is less than or equal to a maximum number of subgroups into which the set of sidelink resources is splitable.

32. The method of claim 1, further comprising receiving a radio resource control (RRC) message that indicates a maximum number of subgroups.

33. The UE of claim 15, wherein the number of subgroups of sidelink resources in the set of sidelink resources is less than or equal to a maximum number of subgroups into which the set of sidelink resources is splitable.

34. The UE of claim 15, wherein the processor-readable code that, when executed by the at least one processor, is further configured to cause the UE to receive a radio resource control (RRC) message that indicates a maximum number of subgroups.
